(19) United States
(12) Patent Application Publication
(10) Pub. No.: US 2006/0115744 A1
(43) Pub. Date: Jun. 1, 2006

(54) Method of producing a mask blank for photolithographic applications, and mask blank

(76) Inventors: Lutz Aschke, Wetter (Ruhr) (DE); Frank Sobel, Meiningen (DE); Guenter Hess, Meiningen (DE); Hans Becker, Meiningen (DE); Markus Renno, Meiningen (DE); Frank Schmidt, Jena (DE); Oliver Goetzberger, Meiningen (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 11/198,387

(22) Filed: Aug. 8, 2005

Related U.S. Application Data
(60) Provisional application No. 60/599,019, filed on Aug. 6, 2004.

(51) Int. Cl. G03F 1/00; B05D 1/04; B32B 9/00; B32B 17/10; B32B 17/06

(52) U.S. Cl. 430/5; 428/428; 428/430; 427/471

(57) ABSTRACT

The invention relates to a method of producing a mask blank (1) for photolithographic applications, particularly in EUV lithography, comprising the steps of: providing a substrate (2) which has a front side (4) and a rear side (3);
depositing an electrically conductive layer (5) on the rear side of the substrate;
depositing a coating on the front side of the substrate, wherein the coating comprises at least a first layer (6) and a second layer (9); and
structuring the coating (6, 9) for photolithographic applications; wherein
a respective handling area (22; 22a-22c) is formed on the front side (4) at least at one predefined location, said handling area not being structured for photolithographic applications and being designed for the handling of the mask blank (1) by means of a mechanical clamp or handling device, and wherein
the first layer (6) is exposed in the respective handling area (22; 22a-22c) so that, when the mask blank (1) is handled from the front side, the mechanical clamp or handling device bears against the first layer (6). The invention furthermore relates to a corresponding mask blank.

This application claims the benefit of the filing date of U.S. Provisional Application Ser. No. 60/599,019 filed Aug. 6, 2004 which is incorporated by reference herein.

### FIELD OF THE INVENTION

The present invention relates in general to the production of a mask blank for photolithographic applications, particularly in EUV lithography (extreme ultraviolet lithography) in the region of approximately 13 nm. In particular, the present invention relates to a method of producing a mask blank which can be suitably handled for photolithographic applications, particularly in EUV lithography, and to a mask blank provided in this way.

### PRIOR ART

In order to achieve increasingly high integration densities in microelectronics but also in other applications, such as Microsystems engineering for example, it is necessary to use increasingly short wavelengths for photolithographic exposure. It can even now be foreseen that, in future, wavelengths in the region of around 13 nm will be used to produce structures having widths of less than around 35 nm. The production of highly precise mask blanks for photolithography is of great importance here. Mask blanks must be essentially free of defects, since otherwise even the smallest errors in the photomask would be reproduced on each chip. All the causes which lead to soiling of or damage to the photomask, be this during production thereof or subsequent handling thereof by means of electrostatic chucks or mechanical clamps or handling devices, must be ruled out to the greatest possible extent.

This requires highly precise techniques for producing mask blanks and extremely careful holding and handling of mask blanks in order to as far as possible prevent mechanical abrasion and the formation of particles. Since a photomask is used to expose a large number of semiconductor substrates, a high outlay in terms of the production and handling of mask blanks or photomasks is justified. Even the smallest improvements in this field warrant a relatively high outlay. It is therefore moreover not surprising that methods which are used in the production and handling of mask blanks or photomasks can be relatively complicated and expensive. This is because even the slightest improvements in yield when producing integrated circuits and the like may justify a high outlay.

From the prior art, electrostatic chucks are known for holding semiconductor substrates which are provided on the rear side with an electrically conductive coating. On account of the relatively large contact area between the chuck and the electrically conductive coating on the rear side of the substrate, only low pressure forces arise during the holding operation, and this reduces the abrasion and mechanical stress on the rear-side coating. The associated patent application DE 103 17 792.2, “Mask blank for use in EUV lithography and method for its production”, which was applied for on 16 Apr. 2003, and the corresponding U.S. patent application Ser. No. 10/825,681, which was applied for on 16 Apr. 2004 by the Applicant, disclose a mask blank with an electrically conductive rear-side coating. This rear-side coating is applied by means of ion-assisted deposition (Ion Beam Deposition; IBD), in particular ion-beam-assisted sputtering, and this leads to highly abrasion-proof and resistant coatings. The content of the two aforementioned patent applications is hereby expressly incorporated by way of reference into the present application for the purposes of the disclosure, particularly with regard to the properties of the rear-side coating and a method for depositing the latter.

DE 102 39 858 A1 (corresponding to US 2004 041 102 A1) discloses a method and configuration for compensating for unevenness in the surface of a substrate. A multilayer reflection coating is applied to the front side of the substrate. An electrically conductive rear-side coating of the EUV reflection mask is also disclosed.

Coatings on side walls of substrates are relatively rare in microelectronics but are not known in the field of mask blanks, particularly for EUV lithography. JP 03-212 916 A discloses a multilayer thin-film capacitor in which a protective layer is applied to side faces of an insulating substrate. JP 2001-291 661 A discloses a method of producing a reflection mask in which a number of layers are deposited on a front side of a substrate, wherein conical structures are prevented from forming when the coating is structured on the front side by overetching.

U.S. Pat. No. 5,756,237 discloses a method of producing a projection mask in which wedge-shaped grooves are formed in the rear side of a mask substrate by wet etching, along which grooves the projection masks are separated by splitting. During production of the projection mask, side edges of the mask substrate may be covered with a photoresist layer. However, this side edge coating is removed again.

US 2003/0031934 A1 discloses a photomask comprising a substrate on which structures are formed. A transparent, electrically conductive layer is applied over the substrate and patterns so that the different areas of the pattern are all kept at the same electrical potential, as a result of which damage due to an electrostatic discharge is prevented. However, the non-structured areas are not used for handling by means of a mechanical clamp or handling device.

US 2002/0076625 A1 discloses a mask blank for EUV lithography comprising a substrate on which a multilayer reflection layer is provided for reflecting EUV radiation. An absorption layer for absorbing the EUV radiation is applied to the multilayer reflection layer.

In order to hold or handle mask blanks by means of mechanical devices, it may be necessary to handle the mask blanks or photomasks subsequently produced therefrom from the front side. In order to prevent abrasion, it has been proposed by the company ASML for example to provide special handling areas on the front side of the substrate, which handling areas must remain uncoated. In such areas, therefore, the mechanical clamp or handling device will bear directly against the front side of the mask substrate. Because the front side of the mask substrate is very flat and has only a slight surface roughness, mechanical abrasion during holding or handling of the mask can also be prevented in this way.

Such a mask layout is shown in FIG. 3. As shown in FIG. 3, a pattern area 20 is provided on the front side of the mask blank 1, in which pattern area the actual photomask is formed by structuring or patterning. A number of areas which are not provided with reference numbers are furthermore reserved at the edge regions. An unstructured area 21 is also provided on the front side, said unstructured area surrounding the pattern area 20. Reference numbers 22a-22c denote separate handling areas which as proposed by ASML are to remain uncoated.

### SUMMARY OF THE INVENTION

According to a first aspect of the present invention, a method is to be provided for producing a mask blank for photolithographic applications, in order to create a mask blank which can be handled in a simpler and more reliable manner. According to a further aspect of the present invention, a method is to be provided for producing a mask blank which can be produced in a cost-effective manner and can be held and handled with reduced abrasion and reduced particle formation both during production and also in subsequent use. According to a further aspect of the present invention, such a mask blank is to be provided which can be earthed in an advantageously simpler and more reliable manner, particularly during handling or machining of the mask blank. According to further aspects of the present invention, corresponding mask blanks are also to be provided.

According to the present invention, there is provided a method of producing a mask blank for photolithographic applications, particularly in EUV lithography, comprising the following steps:

providing a substrate which has a front side and a rear side;

depositing an electrically conductive layer on the rear side of the substrate;

depositing a coating on the front side of the substrate, wherein the coating comprises at least a first layer and a second layer; and

structuring the coating for photolithographic applications;

wherein a respective handling area is formed on the front side at least at one predefined location, said handling area not being structured for photolithographic applications and being designed for the handling of the mask blank by means of a mechanical clamp or handling device, and wherein

the first layer is exposed in the respective handling area so that, when the mask blank is handled from the front side, the mechanical clamp or handling device bears against the first layer.

The present invention is thus based on the knowledge that handling of mask blanks in a way that is gentle on the material and causes little abrasion can be achieved not just when, as proposed in the prior art, uncoated handling areas are reserved on the front side of the mask blank, but rather also when suitable coatings are provided in the handling areas. Usually, the surfaces of mask blanks are very flat and have a low residual roughness. As the inventors have found, such surfaces are suitable for forming relatively defect-free and very homogeneous coatings by means of deposition. Such coatings are also characterized by a high planarity and a low defect density, so that such coatings are also highly abrasion-resistant and can be subjected to relatively high stresses.

It is advantageous that fewer method steps and/or simpler method steps can be used to form the front-side coating. In particular, the front side of the mask substrate can be treated over the entire surface at least in some of the method steps, without complicated masking techniques or etching techniques being necessary in order to form handling areas.

According to a further embodiment, the coating is deposited in such a way that side walls of the substrate are covered at least in some areas, wherein the coating is electrically conductive. The mask blank can thus also be electrically contacted on the side faces. This may be desirable for example so as to earth the mask blank, in order to prevent undesirable charging, caused by irradiation for example, and/or to keep the mask at a defined potential. This is because the mask blank can then be held in an even more reliable and reproducible manner by means of an electrostatic chuck. This earthing from the side of the mask blank can also be used to suppress the occurrence of uncontrolled discharges, which could destroy the mask.

According to another embodiment, the coating is furthermore deposited in such a way that it makes contact with the electrically conductive coating on the rear side of the substrate. The front side of the mask blank can thus also be contacted in the region of the handling areas where the coating, in particular the first layer thereof, is exposed. This represents another important advantage which can be achieved according to the present invention since the-mask blank according to the invention can be reliably earthed optionally from the front side, from the side wall or from the rear side. In particular, the same devices can also be used for earthing purposes as are used for handling of the mask blank.

In order to deposit the electrically conductive coating on the rear side of the mask substrate, the latter can be held by a mechanical clamp which approaches from the front side or from side faces of the mask substrate. Once the electrically conductive layer has been applied to the rear side of the mask substrate, the latter can be reliably held during subsequent method steps by means of an electrostatic chuck which engages from the rear side of the mask substrate. Side walls of the mask substrate may likewise be exposed and thus lead to the deposition of an electrically conductive layer on the side walls.

According to a further embodiment, a buffer or stress compensation layer may furthermore be formed on the first layer deposited on the front side, which buffer layer or stress compensation layer can form the second layer of the front-side coating. According to one embodiment, the buffer or stress compensation layer may also be deposited in the handling areas. According to a further embodiment, however, for example by suitably masking the front side during the deposition, the buffer or stress compensation layer can be prevented from being deposited in the handling areas. In this way, it can be ascertained whether a mechanical clamp or handling tool in the handling areas bears against the multilayer layer or against the buffer or stress compensation layer during mechanical handling of the mask blank from the front side.

According to another embodiment, an absorber layer may furthermore be deposited on the buffer or stress compensation layer, which absorber layer may consist for example of chromium (Cr), TaN or doped TaN. In order to deposit the absorber layer, the mask substrate can be held by an electrostatic chuck or mechanical clamp.

According to one embodiment, the front side is masked during the deposition, so that the absorber layer is not formed in the handling areas. According to a further embodiment, the front side of the mask substrate is not masked and the handling areas are exposed again subsequently, for example by wet etching, in such a way that either the multilayer layer or the buffer or stress compensation layer is exposed in the handling areas.

According to a further embodiment, a stress compensation layer is firstly applied prior to the deposition of the electrically conductive layer on the rear side of the substrate, in order to compensate stress of the rear-side coating.

According to a further embodiment, the stress compensation layer may for this purpose comprise tantalum nitride, and in particular may consist essentially completely thereof. The chemical composition may in particular be given as follows: a content of tantalum of between 45 atom % and 65 atom %, preferably a content of tantalum of between 47 atom % and 62 atom %; and a content of nitrogen of between 35 atom % and 55 atom %, preferably a content of nitrogen of between 38 atom % and 50 atom %. The layer thickness of this layer may be in the range between 172 nm and 178 nm and is preferably 175 nm. The actual electrically conductive coating is applied to such a stress compensation layer.

According to a further embodiment, the electrically conductive layer may in particular have the following composition: a content of chromium of between 88 atom % and 90 atom %, preferably a content of chromium of between 88.5 atom % and 89.5 atom %; a content of nitrogen of between 9 atom % and 11.5 atom %, preferably a content of nitrogen of between 9.5 atom % and 11 atom %; and a content of carbon of between 0.7 atom % and 0.9 atom %, preferably a content of carbon of 0.8 atom %. The layer thickness of this electrically conductive layer may be in the range between 58 nm and 62 nm and is preferably 60 nm. In principle, however, any other metals are suitable according to the invention for forming the electrically conductive layer.

In order to deposit optionally one, several or all of the aforementioned layers, use may be made according to the invention of an ion-beam-assisted deposition method (Ion Beam Deposition; IBD), in particular ion-beam-assisted sputtering. In this way, particularly homogeneous and relatively defect-free layers can be formed with low residual roughness.

Thus, according to the invention, devices for handling mask blanks can at the same time also be used to earth a mask blank according to the invention, namely optionally from the front side, the side wall or the rear side of the mask blank.

### BRIEF DESCRIPTION OF THE DRAWINGS

The invention will be described below by way of example and with reference to the appended drawings, and further features, advantages and objects to be achieved will emerge therefrom. In the drawings:

FIG. 1 shows in schematic section a mask blank according to a first embodiment of the present invention;

FIG. 2 shows in schematic section a mask blank according to a second embodiment of the present invention;

FIG. 3 shows in schematic plan view a mask blank according to the present invention;

FIG. 4 shows in a partial plan view a mask blank according to a third embodiment of the present invention;

FIG. 5 shows in a flowchart a method according to the present invention;

FIG. 6 shows in a flowchart a modification of the method as shown in FIG. 5; and

FIG. 7 shows in a flowchart a modification of the method as shown in FIG. 6.

### DETAILED DESCRIPTION OF EXEMPLARY EMBODIMENTS

In the figures, identical reference numbers denote elements or groups of elements which are identical or which act in essentially the same way.

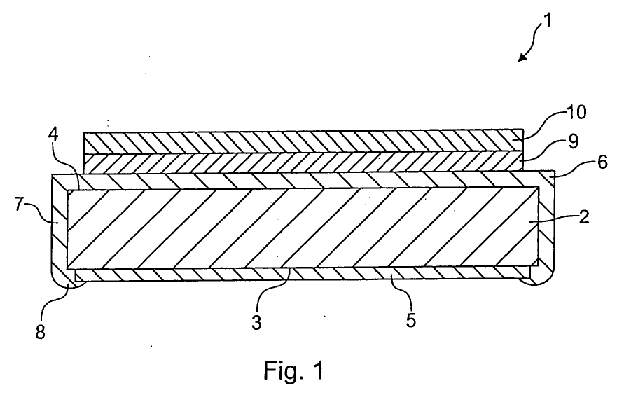

As shown in FIG. 1, the mask blank denoted overall by 1 comprises a substrate 2 which is formed of a conventional LTE material (Low Thermal Expansion material), for example the Applicant's Zerodur®. The substrate 2 has a rear side 3 and a front side 4. As shown in FIG. 1, an electrically conductive coating 5 is deposited on the rear side 3, said electrically conductive coating essentially completely covering the rear side 3. Further details regarding the rear-side coating and a method of forming the latter are disclosed in the associated patent application DE 103 17 792 “Mask blank for use in EUV lithography and method for its production”, which was applied for on 16 Apr. 2003, and in the corresponding U.S. patent application Ser. No. 10/825,618, which was applied for on 16 Apr. 2004 by the Applicant, the content of which is hereby expressly incorporated by way of reference into the present application. As described therein, the electrically conductive rear-side coating is applied by ion-beam-assisted deposition (IBD), in particular ion-beam-assisted sputtering, and it is characterized by a very high abrasion resistance. In particular, the resistance of the electrically conductive coating to abrasion with a cloth according to DIN 58196-5 (DIN=German Industrial Standard) falls at least into category 2, the resistance of the electrically conductive coating to abrasion with an eraser according to DIN 58196-4 falls at least into category 2 and the adhesion strength of the electrically conductive coating when tested with an adhesive tape according to DIN 58196-2 corresponds to a detachment of essentially 0%. It is furthermore disclosed therein that the specific resistance of the electrically conductive coating at a layer thickness of around 100 nm is at least around 10⁻⁷ Ωcm, preferably at least around 10⁻⁶ Ωcm, and even more preferably at least around 10⁻⁵ Ωcm. A mask blank coated on the rear side in this way can be held or handled by means of electrostatic chucks on the rear side without the risk of mechanical abrasion or particles caused by the handling.

As shown in FIG. 1, a multilayer layer 6, in particular a Si/Mo multilayer layer, is formed on the front side 4, which multilayer layer can be designed and used in the known manner to reflect radiation, particularly EUV radiation. As shown in FIG. 1, the multilayer layer 6 also covers side walls of the substrate 2 in the regions 7. On the rear side, as shown schematically in FIG. 1, the multilayer layer 6 makes contact with the electrically conductive rear-side coating 5. This contact point 8 may of course be formed at the lower edge of the side-wall coating 7 and more or less flush with a respective side wall of the substrate 2. According to another embodiment (not shown), the electrically conductive rear-side coating 5 may also slightly cover the lower longitudinal edge of the substrate 2, so that the contact point between the electrically conductive rear-side coating 5 and the multilayer layer 6 may also be formed in the region of the side walls of the substrate 2. As shown in FIG. 1, the electrically conductive coating 5 does not completely cover the rear side 3 of the substrate 2, but rather an edge region of the substrate 2 is not covered by the electrically conductive coating 5 at least in some areas, and this will be described in more detail below.

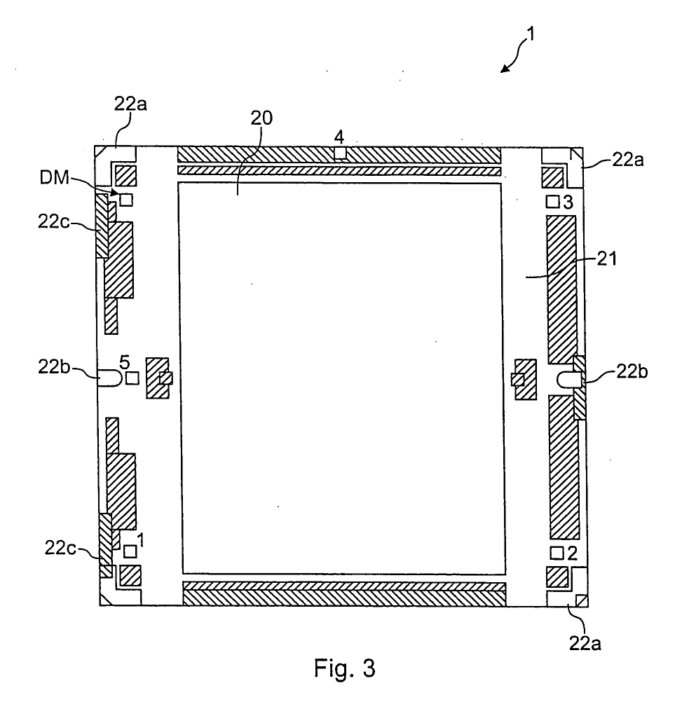

As shown in FIG. 1, further layers are applied to the multilayer layer 6, namely a buffer layer or stress compensation layer 9, for example consisting of SiO₂, Si, Ru or Ta₂O₅, and an absorber layer 10, for example consisting of Cr, TaN or doped TaN, in particular doped with Bor, C or Ge. The absorber layer 10 and the buffer layer 9 may be photolithographically structured or patterned in the known manner in order to form a mask area 20 (cf. FIG. 3) in the central region of the mask blank 1. As can be seen from FIGS. 1 and 3, according to the invention edge regions on the front side of the mask blank 1 are not provided with the buffer layer 9 and/or the absorber layer 10. In such regions, therefore, the multilayer layer 6 is exposed in the first embodiment. According to the first embodiment, such exposed multilayer layer regions are used to form handling areas on the front side of the mask blank 1, against which handling areas a mechanical clamp or handling device can bear directly when handling the mask blank from the front side. According to the invention, these exposed surface areas of the multilayer layer 6 are sufficiently abrasion-resistant and can be subjected to stress, so that handling from the front side is permitted in the handling area 22.

According to the first embodiment, the uppermost layer of the multilayer layer 6 has a certain minimum electrical conductivity, so that, when the substrate is handled from the front side, the mask blank 1 can be earthed by contacting in the handling areas (cf. FIG. 3). Earthing currents are thus passed via the multilayer layer 6, in particular the uppermost layer thereof, from the handling areas 22 (cf. FIG. 3) via the side wall regions 7 and the contact point 8 to the electrically conductive rear coating 5, from where they can flow out via the electrostatic chuck (not shown). Even in the case of uncontrolled discharges, the mask can thus still be held securely by the electrostatic chuck because the mask can be kept at a defined potential. The earthing may also be necessary in order to prevent undesirable charging, for example upon irradiation of a photoresist layer, particularly during writing with an electron beam. Overall, the mask blank 1 can be reliably held by means of an electrostatic chuck because the mask blank 1 can always be kept at a defined potential.

The uppermost layer of the multilayer layer 6 may be a silicon layer. This is applied with a sufficient thickness, for example with a thickness of at least 11 nm, so that only about the top 3 nm of the silicon layer will be oxidized whereas the rest will remain unoxidized and is thus sufficiently electrically conductive. Alternatively, the uppermost top layer of the multilayer layer 6 may also be formed of any other suitably abrasion-resistant materials, for example Ru, Ta₂O₅ and the like.

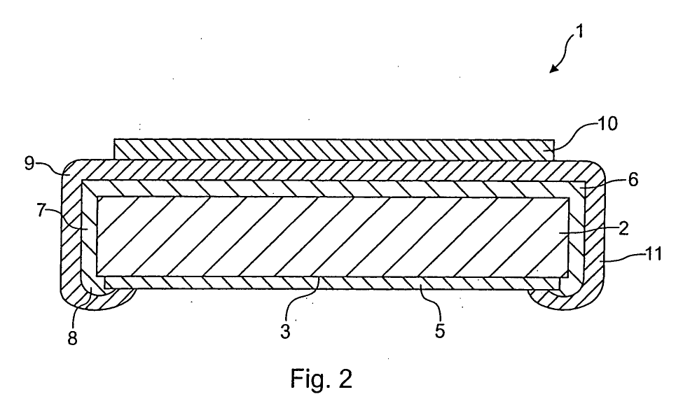

FIG. 2 shows in schematic section a mask blank according to a second embodiment of the present invention. Unlike in FIG. 1, the buffer or stress compensation layer is also formed on the side edge regions 7 of the mask blank 1 and extends up to the rear-side contact points 8. As an alternative, only the side wall regions 7 may be covered at least in some areas by the buffer or stress compensation layer 9. An SiO₂ layer is particularly suitable as the buffer or tension compensation layer 9. However, any other materials may also be used, as will be readily obvious to the person skilled in the art. According to the second embodiment, contacting in the handling areas 22 (cf. FIG. 3) may in principle also be brought about in that an earthing rod or the like is pushed through the buffer layer 9 in order to make contact with electrically conductive layers located therebelow. This may take place in particular on the side walls of the mask blank 1. According to the second embodiment, a mechanical clamp or handling device which approaches from the front side of the mask blank 1 bears directly against the buffer layer 9 in the handling areas.

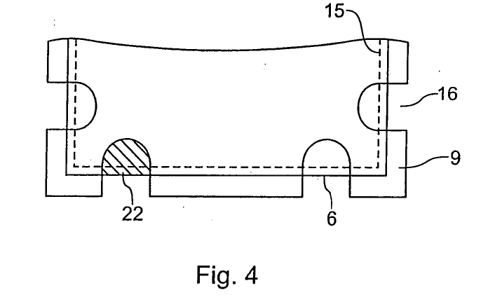

If this is to be prevented, according to a third embodiment which is shown in FIG. 4, one or more cutouts 16 may be formed in the buffer layer 9 at the handling areas 22, as described in more detail below, where the multilayer layer 6 located therebelow is exposed. According to the third embodiment, the chuck or handling device, as in the first embodiment, can bear directly against the multilayer layer 6 in the handling area 22.

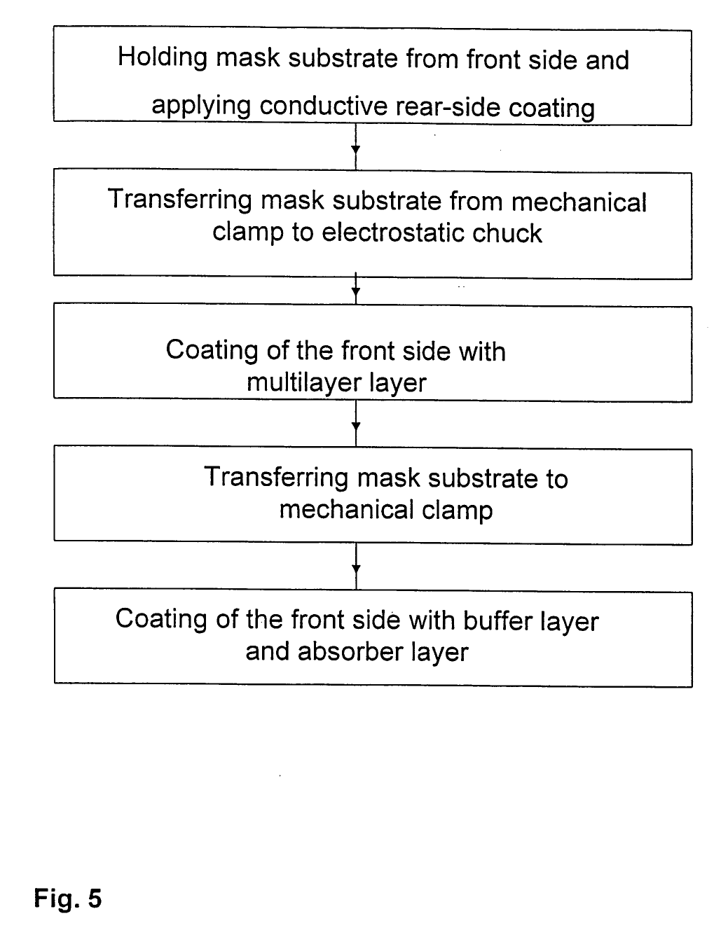

Hereinbelow, a method of producing a mask blank according to the present invention will be described with reference to FIG. 5. As will become clear from the following description, the substrate is held optionally by a mechanical clamp or an electrostatic chuck.

As shown in FIG. 5, the mask substrate is firstly held by means of a mechanical clamp which approaches from the front side of the mask substrate, in order to deposit an electrically conductive layer on the rear side. For this purpose, use is preferably made of an ion-beam-assisted sputtering method. The mask substrate which is coated on the rear side is then transferred to an electrostatic chuck which bears against the electrically conductive rear-side coating and holds the mask substrate from the rear side. The multilayer layer is then deposited on the front side. This multilayer layer covers the entire front side of the substrate. The uppermost layer of the multilayer layer has a certain minimum electrical conductivity which is sufficient for earthing the front side of the mask substrate. Because the side walls of the mask substrate are exposed during the deposition of the multilayer layer, a certain coating of the side walls with the multilayer layer undoubtedly also takes place, the uppermost top layer of said multilayer layer having a certain minimum conductivity. There is unavoidably thus a conductive coating of the side walls of the mask substrate.

As shown in FIG. 5, the mask substrate is then transferred to a mechanical clamp and is held by the latter. The buffer layer and the absorber layer are then deposited on the front side of the mask substrate. During the deposition of the buffer layer and absorber layer, a mask is used in the region of the handling areas which are to be formed (cf. FIG. 3), so that the multilayer layer is not further coated in the region of the handling areas. In this way, the mask blank shown in FIG. 1 can be formed.

Instead of transferring the mask substrate to a mechanical clamp in order to deposit the buffer layer and absorber layer, it may also in principle be provided according to the invention to deposit the buffer layer and absorber layer while the mask substrate is held by the same electrostatic chuck or a different electrostatic chuck from the rear side.

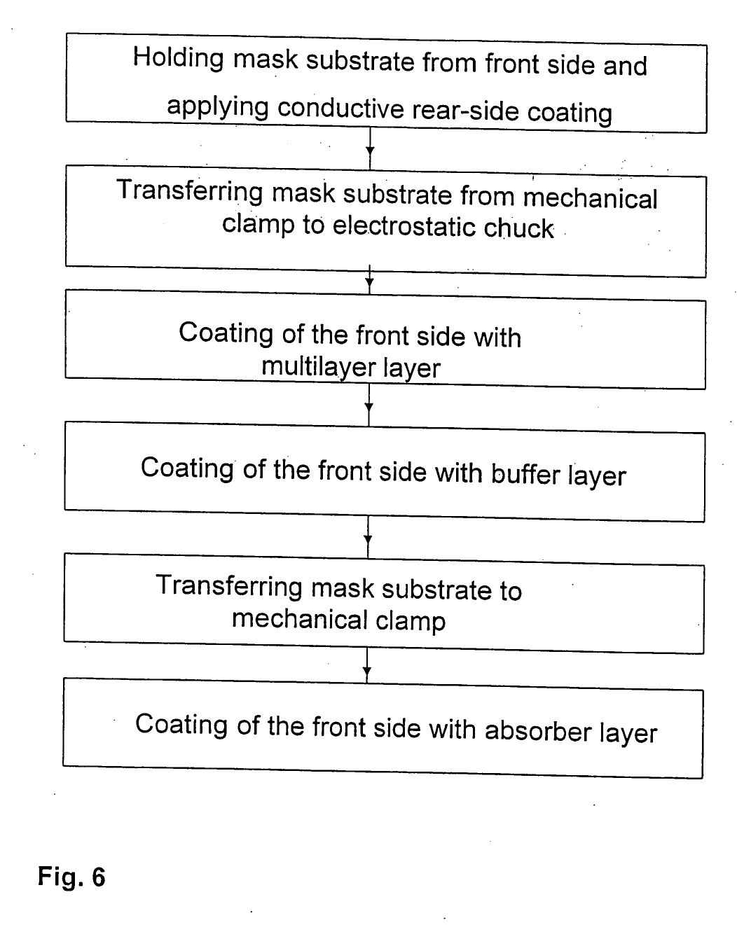

In the modification of the method of FIG. 5, said modification being shown in FIG. 6, the buffer layer is deposited on the front side of the mask substrate while the mask substrate is still held by the electrostatic chuck. The buffer layer is thus also deposited on the side walls of the mask substrate, in order to form the mask blank according to the second embodiment as shown in FIG. 2.

As shown in FIG. 6, the mask substrate is then transferred to a mechanical clamp and the absorber layer is then deposited on the front side. During the deposition of the absorber layer, use is once again made of a mask in order to prevent deposition of the absorber layer in the handling areas. In this way, it is also possible to form the mask blank as shown in FIG. 4.

Of course, as shown in FIG. 6, the absorber layer may also be deposited on the front side of the mask substrate when the latter is held by the same electrostatic chuck or a different electrostatic chuck from the rear side.

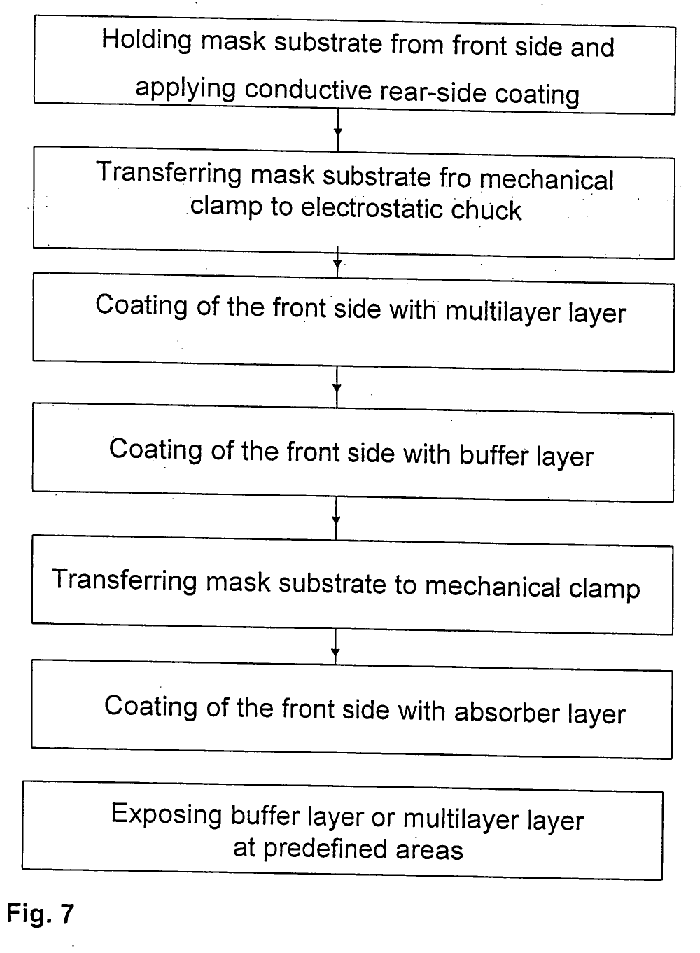

FIG. 7 shows a further modification of the method shown in FIG. 6. In this case, no mask is used during the deposition of the absorber layer on the front side, so that the front side of the mask substrate is completely covered by the absorber layer. Only in a subsequent method step is the buffer layer or stress compensation layer located below the absorber layer or the multilayer layer located below the buffer layer exposed at the predefined handling areas, for example by wet etching. Finally, a mask blank as shown in FIG. 2 or FIG. 4 can thus be obtained. Of course, in the method shown in FIG. 7, it is also possible for the absorber layer to be deposited on the front side of the mask substrate when the latter is held by the same electrostatic chuck or a different electrostatic chuck from the rear side.

As will be readily obvious to the person skilled in the art when studying the above description, it is possible for a stress compensation layer, comprising tantalum nitride, to be firstly applied before the electrically conductive layer is applied to the rear side of the substrate, in order to compensate stress of the electrically conductive layer, as mentioned above. A second layer, consisting of chromium, nitrogen and carbon, can be applied to this stress compensation layer, as mentioned above.

As will be readily obvious to the person skilled in the art when studying the above description, further modifications and changes may be made without departing from the general concept of the solution, as described above, or from the scope of protection of the appended patent claims. In particular, any materials other than the aforementioned materials may also be used to form a mask blank for photolithography, particularly EUV photolithography. Furthermore, a stress compensation layer may also be provided alternatively or additionally below the multilayer layer. These and other modifications and changes are therefore intended to be expressly included in the scope of protection of the appended patent claims.

### LIST OF REFERENCE NUMBERS

1 mask blank
2 substrate
3 rear side
4 front side
5 electrically conductive rear-side coating
6 Si/Mo multilayer layer
7 Si/Mo multilayer layer on side wall of substrate 2
8 contact point
9 buffer layer
10 absorber layer
11 buffer layer on side wall of substrate 2
15 edge of substrate 2
16 cutout in buffer layer 9
20 pattern area
21 unstructured area
22 handling area
22a handling area close to corner region of mask blank 1
22b central handling area
22c further handling area

Without further elaboration, it is believed that one skilled in the art can, using the preceding description, utilize the present invention to its fullest extent. The preceding preferred specific embodiments are, therefore, to be construed as merely illustrative, and not limitative of the remainder of the disclosure in any way whatsoever.

In the foregoing and in the examples, all temperatures are set forth uncorrected in degrees Celsius and, all parts and percentages are by weight, unless otherwise indicated.

The entire disclosures of all applications, patents and publications, cited herein and of corresponding U.S. Provisional Application Ser. No. 60/599,019, filed Aug. 6, 2004, are incorporated by reference herein.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

What is claimed is:

1. A method of producing a mask blank for photolithographic applications, particularly in EUV lithography, comprising the steps of:
providing a substrate which has a front side and a rear side;
depositing an electrically conductive layer on the rear side of the substrate;
depositing a coating on the front side of the substrate, wherein the coating comprises at least a first layer and a second layer; and
structuring the coating for said photolithographic applications; wherein
a respective handling area is formed on the front side at least at one predefined location, said handling area not being structured for the photolithographic applications and being designed for the handling of the mask blank by means of a mechanical clamp or handling device, and wherein
the first layer is exposed in the respective handling area so that, when the mask blank is handled from the front side, the mechanical clamp or handling device bears against the first layer.

2. The method according to claim 1, in which the coating is deposited in such a way that side walls of the substrate are covered at least in some areas, wherein the coating is electrically conductive.

3. The method according to claim 2, in which the coating is furthermore deposited in such a way that it makes contact with the electrically conductive coating on the rear side of the substrate.

4. The method according to claim 2, in which the substrate is held by means of a mechanical clamp or handling device in order to deposit the electrically conductive layer, and the substrate is transferred to an electrostatic chuck prior to the deposition of the first layer on the front side so that the first layer is deposited on the front side while the substrate is held by means of the electrostatic chuck.

5. The method according to claim 4, in which a surface of the coating is formed of Si or SiO₂.

6. The method according to claim 5, in which the first layer is formed as a Si/Mo multilayer.

7. The method according to claim 4, in which a stress compensation layer is furthermore formed on the first layer, said stress compensation layer forming the second layer.

8. The method according to claim 7, in which the stress compensation layer is formed of Cr or SiO₂.

9. The method according to claim 7, in which the stress compensation layer is formed in such a way that side walls of the substrate are embraced.

10. The method according to claim 4, in which an absorber layer is furthermore deposited on the front side of the mask blank, in order to weaken or absorb radiation used for the photolithographic application.

11. The method according to claim 4, in which the substrate is transferred to a mechanical clamp or handling device prior to the deposition of the stress compensation layer and of the absorber layer, said mechanical clamp or handling device holding the substrate from the rear side, wherein at least one area on the front side of the substrate is masked so that the stress compensation layer and the absorber layer are formed with at least one opening at a respectively predefined handling area and so that the first layer located therebelow is exposed.

12. The method according to claim 4, in which the substrate is transferred to a mechanical clamp or handling device prior to the deposition of the absorber layer, said mechanical clamp or handling device holding the substrate from the rear side, wherein at least one area on the front side of the substrate is masked so that the absorber layer is formed with at least one opening at a respectively predefined handling area and so that the first layer located therebelow is exposed.

13. The method according to claim 10, in which the absorber layer is formed of Cr, TaN or doped TaN.

14. The method according to claim 10, in which the absorber layer is formed by ion-beam-assisted sputtering.

15. The method according to claim 1, wherein a stress compensation layer is firstly applied prior to the deposition of the electrically conductive layer on the rear side of the substrate.

16. The method according to claim 15, wherein the stress compensation layer has the following composition:
a content of tantalum of between 45 atom % and 65 atom %, preferably a content of tantalum of between 47 atom % and 62 atom %; and
a content of nitrogen of between 35 atom % and 55 atom %, preferably a content of nitrogen of between 38 atom % and 50 atom %;
wherein the thickness of the stress compensation layer is in the range between 172 nm and 178 nm and is preferably 175 nm.

17. The method according to claim 1, wherein the electrically conductive layer has the following composition:
a content of chromium of between 88 atom % and 90 atom %, preferably a content of chromium of between 88.5 atom % and 89.5 atom %;
a content of nitrogen of between 9 atom % and 11.5 atom %, preferably a content of nitrogen of between 9.5 atom % and 11 atom %; and
a content of carbon of between 0.7 atom % and 0.9 atom %, preferably a content of carbon of 0.8 atom %;
wherein the layer thickness of the electrically conductive layer is in the range between 58 nm and 62 nm and is preferably 60 nm.

18. A mask blank for photolithographic applications, particularly in EUV lithography, comprising
a substrate which has a front side and a rear side;
an electrically conductive layer which is deposited on the rear side of the substrate so that the mask blank can be held by an electrostatic chuck; and
a coating which is deposited on the front side of the substrate, wherein
a respective handling area is provided on the front side at least at one predefined location, said handling area not being structured or provided for the photolithographic applications and being designed for the handling of the mask blank by means of a mechanical clamp or handling device,
characterized in that the coating comprises at least a first layer and a second layer, wherein the first layer is exposed in the respective handling area so that, when the mask blank is handled from the front side, the mechanical clamp or handling device bears against the first layer.

19. The mask blank according to claim 18, in which the coating furthermore covers side walls of the substrate at least in some areas, wherein the coating is electrically conductive.

20. The mask blank according to claim 19, in which the coating furthermore makes contact with the electrically conductive coating on the rear side of the substrate.

21. The mask blank according to claim 20, in which a surface of the coating is formed of Si or SiO₂.

22. The mask blank according to claim 21, in which the coating comprises a Si/Mo multilayer.

23. The mask blank according to claim 20, in which the coating furthermore comprises a stress compensation layer.

24. The mask blank according to claim 23, in which the stress compensation layer comprises Cr or SiO₂.

25. The mask blank according to claim 23, in which the stress compensation layer embraces side walls of the substrate.

26. The mask blank according to claim 23, in which the stress compensation layer has at least one opening which is formed at a respectively predefined handling area so that the first layer located therebelow is exposed.

27. The mask blank according to claims 19, on the front side of which an absorber layer is furthermore deposited, in order to weaken or absorb radiation used for the photolithographic application.

28. The mask blank according to claim 27, in which the absorber layer is formed of Cr, TaN or doped TaN.

29. The mask blank according to claim 18, wherein a stress compensation layer is provided between the electrically conductive layer and the rear side of the substrate.

30. The mask blank according to claim 29, wherein the stress compensation layer has the following composition:
a content of tantalum of between 45 atom % and 65 atom %, preferably a content of tantalum of between 47 atom % and 62 atom %; and
a content of nitrogen of between 35 atom % and 55 atom %, preferably a content of nitrogen of between 38 atom % and 50 atom %;
wherein the thickness of the stress compensation layer is in the range between 172 nm and 178 nm and is preferably 175 nm.

31. The mask blank according to claim 18, wherein the electrically conductive layer has the following composition:
a content of chromium of between 88 atom % and 90 atom %, preferably a content of chromium of between 88.5 atom % and 89.5 atom %;
a content of nitrogen of between 9 atom % and 11.5 atom %, preferably a content of nitrogen of between 9.5 atom % and 11 atom %; and
a content of carbon of between 0.7 atom % and 0.9 atom %, preferably a content of carbon of 0.8 atom %;
wherein the layer thickness of the electrically conductive layer is in the range between 58 nm and 62 nm and is preferably 60 nm.
